(19) United States
(12) Patent Application Publication
(10) Pub. No.: US 2015/0301282 A1
(43) Pub. Date: Oct. 22, 2015

(54) OPTICAL ELEMENT, ILLUMINATION DEVICE, IMAGE DISPLAY DEVICE, METHOD OF OPERATING OPTICAL ELEMENT

(71) Applicant: NEC Corporation, Minato-ku, Tokyo (JP)

(72) Inventors: Masanao NATSUMEDA, Tokyo (JP); Masao IMAI, Tokyo (JP); Shin TOMINAGA, Tokyo (JP); Naofumi SUZUKI, Tokyo (JP); Mizuho TOMIYAMA, Tokyo (JP); Yuji OHNO, Tokyo (JP)

(21) Appl. No.: 14/417,849

(22) PCT Filed: Apr. 22, 2013
(86) PCT No.: PCT/JP2013/061780

§ 371 Date: Jan. 28, 2015

(30) Foreign Application Priority Data
Jul. 31, 2012 (JP) 2012-170683

(51) Int. Cl. G02B 6/122; H01L 51/52; G03B 21/20; H01L 51/50

(52) U.S. Cl. CPC G02B 6/1226; H01L 51/5016; H01L 51/5056; H01L 51/5072; H01L 51/5206; G03B 21/206; G02B 2006/12123

(57) ABSTRACT

Provided is an optical element that highly efficiently radiates light with high directivity at low etendue. The optical element includes a light emission layer (103) generating an exciton to emit light, a plasmon excitation layer (105) having a higher plasma frequency than a light emission frequency of the light emission layer (103), an output layer (107) converting light or a surface plasmon generated on an upper surface of the plasmon excitation layer (105) into light with a predetermined output angle to output the light, and a dielectric layer (102). In the optical element, a real part of an effective dielectric constant with respect to the surface plasmon is higher in an upper side portion than the plasmon excitation layer (105) than in a lower side portion than the plasmon excitation layer (105); a dielectric constant with respect to the light emission frequency of the light emission layer (103) is higher in a lowest layer than in a layer adjacent to a lower side of the plasmon excitation layer (105); and assuming that a radiation angle of a surface plasmon-derived highly directional radiation from the plasmon excitation layer (105) to the output layer (107) side is θ_{out,spp} and a radiation angle of an optical waveguide fundamental mode-derived highly directional radiation is θ_{out,light}, an absolute value of a difference between the θ_{out,spp} and the θ_{out,light} is less than 10 degrees.

### TECHNICAL FIELD

The present invention relates to an optical element, an illumination device, an image display device, and a method for operating an optical element.

### BACKGROUND ART

An image display device such as a projector includes, for example, a light source device having an optical element, an illumination optical system to which light from the light source device is input, a light valve having a liquid crystal display panel to which light from the illumination optical system is input, and a projection optical system for projecting light from the light valve on a projection surface.

The image display device is required to prevent optical loss as much as possible in an optical path from the light source device to the light valve in order to increase luminance of a projected image.

In addition, there is a restriction on the image display device due to an etendue determined by a product of an area of the light source device and an output angle thereof. In other words, light from the light source device is not used as projection light unless a value of the product of the light emission area of the light source device and the output angle thereof is set to be equal to or less than a value of a product of an incidence surface area of the light valve and an acceptance angle (a solid angle) determined by an F-number of a projection lens.

Accordingly, regarding light source devices including an optical element and an optical element to which light from the optical element is input, there has been an unsolved problem in that reduction of the above-mentioned optical loss is achieved by reducing an etendue of light output from the optical element.

As methods for obtaining light with low etendue, there are techniques that apply highly directional radiation caused by interaction between an exciton in a light emitter and a surface plasmon (Patent Literature 1 and Non Patent Literature 1).

An optical element in such techniques emits light based on a principle as follows. First, excitation light applied from the optical element is absorbed in the light emission layer, thereby generating an exciton in the light emission layer. The exciton couples to a free electron in the plasmon excitation layer to excite a surface plasmon. Then, the excited surface plasmon is emitted as light.

### CITATION LIST

### Patent Literature

[PTL 1]: Japanese Unexamined Patent Application Publication No. 2002-64233

### Non Patent Literature

[NPL 1]: The journal of physical chemistry B vol. 108, pp. 12073-12083 (2004)

### SUMMARY OF INVENTION

### Technical Problem

In the optical element described in the Patent Literature 1 or the like, a mode existing in the optical element is only a surface plasmon-derived mode, so that the percentage of power of the exciton contributing to highly directional radiation is limited to around 60%. On the other hand, while increase of the mode increases the amount of light radiating onto a side where the highly directional radiation is taken out, there is a problem with extreme reduction of directivity, as disclosed in Non Patent Literature 1.

It is an object of the present invention to provide an optical element that highly efficiently emit light with high directivity at low etendue, an illumination device, an image display device, and a method for operating an optical element.

### Solution to Problem

In order to achieve the above object, an optical element of the present invention includes a light emission layer, a plasmon excitation layer, an output layer, and a dielectric layer, in which the light emission layer generates an exciton to emit light; the plasmon excitation layer is arranged on an upper side than the light emission layer and has a higher plasma frequency than a light emission frequency of the light emission layer; the output layer is arranged on an upper side than the plasmon excitation layer and converts light or a surface plasmon generated on an upper surface of the plasmon excitation layer into light with a predetermined output angle to output the light; the dielectric layer is arranged at least one of on a lower side than the light emission layer and between the light emission layer and the plasmon excitation layer; a real part of an effective dielectric constant with respect to the surface plasmon is higher in an upper side portion than the plasmon excitation layer than in a lower side portion than the plasmon excitation layer; a dielectric constant with respect to the light emission frequency of the light emission layer is higher in a lowest layer than in a layer adjacent to a lower side of the plasmon excitation layer; and assuming that, in a highly directional radiation from the plasmon excitation layer to the output layer side, a radiation angle of a surface plasmon-derived highly directional radiation is θ_{out,spp} and a radiation angle of an optical waveguide fundamental mode-derived highly directional radiation is θ_{out,light}, an absolute value of a difference between the θ_{out,spp} and θ_{out,light} the is less than 10 degrees.

An illumination device of the present invention includes the optical element of the present invention and a light projection unit, and is capable of projecting light by inputting light from the optical element to the light projection unit and outputting light from the light projection unit.

An image display device of the present invention includes the optical element of the present invention and an image display unit and is capable of displaying an image by inputting light from the optical element to the image display unit and outputting light from the image display unit.

An operation method for the optical element of the present invention includes causing the light emission layer of the optical element of the present invention to generate an exciton, coupling power of the generated exciton to a surface plasmon-derived mode and an optical waveguide mode in the optical element, and then, emitting, as light, the power of the exciton coupled to each mode.

### Advantageous Effects of Invention

The present invention can provide an optical element that highly efficiently radiates light with high directivity at low etendue, an illumination device, an image display device, and an optical element operating method.

### BRIEF DESCRIPTION OF DRAWINGS

FIG. 1 is a perspective view schematically depicting a structure of an example of an optical element of the present invention (a first embodiment);

FIG. 2 is a perspective view for depicting an example of an arrangement of a light emitting element for the example of the optical element of the present invention (the first embodiment);

FIG. 3 is a diagram for depicting a light intensity distribution of a surface plasmon mode and a waveguide fundamental mode in the first embodiment;

FIG. 4A is a chart depicting a normalized in-plane wavenumber dependence of dissipation power from excitons under a condition in which an output angle of the surface plasmon mode matches an output angle of the waveguide fundamental mode in the first embodiment;

FIG. 4B is a chart depicting a dependence of dissipation power from excitons on angle of output to a dielectric layer 106 under the condition in which the output angle of the surface plasmon mode matches the output angle of the waveguide fundamental mode in the first embodiment;

FIG. 5 is a perspective view schematically depicting a structure of an example of a light emitting element of the present invention (a second embodiment); and

FIG. 6 are schematic diagrams depicting a structure of an example of an image display device (a projector) of the present invention (a third embodiment).

### DESCRIPTION OF EMBODIMENTS

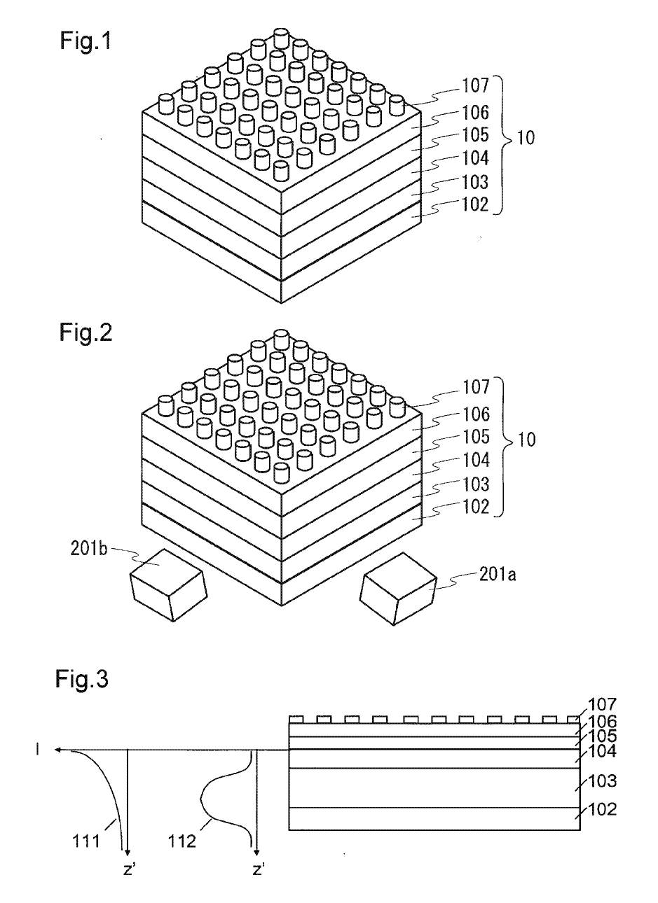

Hereinafter, a detailed description will be given of exemplary embodiments as examples of an optical element, an illumination device, and an image display device of the present invention with reference to the drawings. However, the present invention is not limited to the following exemplary embodiments. In FIGS. 1 to 6 below, the same portions are given the same reference signs, and a description thereof may be omitted. In addition, for descriptive convenience in the drawings, a structure of each portion may be simplified as needed for illustration, and a dimensional ratio and the like of each portion may be different from actual ones to be schematically illustrated. Additionally, the term “dielectric constant” represents a relative dielectric constant, unless otherwise specified.

### First Exemplary Embodiment

An optical element of the present exemplary embodiment is an example of an optical element including a dielectric layer. A perspective view of FIG. 1 depicts a structure of the optical element of the present exemplary embodiment.

As depicted in FIG. 1, an optical element 10 of the present exemplary embodiment includes a dielectric layer 102, a light emission layer 103 laminated on the dielectric layer 102, a dielectric layer 104 laminated on the light emission layer 103, a plasmon excitation layer 105 laminated on the dielectric layer 104, a dielectric layer 106 laminated on the plasmon excitation layer 105, and a wavenumber vector conversion layer (an output layer) 107 laminated on the dielectric layer 106.

The optical element 10 is configured such that a real part of an effective dielectric constant with respect to a surface plasmon in an excitation light incident side portion (which may be hereinafter referred to as “incident side portion”) is lower than a real part of an effective dielectric constant with respect to the surface plasmon in a light output side portion (which may be hereinafter referred to as “output side portion”), and the real part of the effective dielectric constant is lower than a real part of an effective dielectric constant (the square of an equivalent refractive index) with respect to an optical waveguide fundamental mode in the incident side portion. The incident side portion includes an entire structure laminated on a side of the plasmon excitation layer 105 facing the light emission layer 103 and an ambient atmosphere medium (which may be hereinafter referred to as “medium”) in contact with the light emission layer 103. The entire structure includes the dielectric layer 104 and the light emission layer 103. The output side portion includes an entire structure laminated on a side of the plasmon excitation layer 105 facing the wavenumber vector conversion layer 107 and a medium in contact with the wavenumber vector conversion layer 107. The entire structure includes the dielectric layer 106 and the wavenumber vector conversion layer 107. For example, the dielectric layer 104 and the dielectric layer 106 are not necessarily essential constituent elements when, even if the dielectric layer 104 and the dielectric layer 106 are removed, the real part of the effective dielectric constant with respect to the surface plasmon in the incident side portion is lower than the real part of the effective dielectric constant with respect to the surface plasmon in the output side portion and the real part of the effective dielectric constant with respect to the surface plasmon in the incident side portion is lower than the real part of the effective dielectric constant with respect to the optical waveguide fundamental mode in the incident side portion.

Herein, the effective dielectric constant with respect to the surface plasmon is determined by a dielectric constant distribution of the incident side portion or the output side portion and a distribution of a surface plasmon relative to a direction perpendicular to an interface of the plasmon excitation layer 105. Assuming that directions parallel to the interface of the plasmon excitation layer 105 are x and y axes, and the direction perpendicular to the interface of the plasmon excitation layer 105 (when concaves and convexes are formed on a surface of the plasmon excitation layer 105, a direction perpendicular to an average surface thereof) is a z axis, and when the light emission layer 103 alone is excited by excitation light, an angle frequency of light emitted from the light emission layer 103 is ω, a dielectric constant distribution of a dielectric material in the incident side portion or the output side portion relative to the plasmon excitation layer 105 is ∈(ω, x, y, z), a z component of a wavenumber of the surface plasmon is k_{spp,z}, Im[ ] is a symbol representing an imaginary part of a numerical value in [ ], and ∥ is a symbol representing an absolute value of a value in ∥, an effective dielectric constant (∈_{eff,spp}) with respect to the surface plasmon is represented by the following formula (1):

$${ɛ}_{eff , spp} = {( \frac{\int {\int }_{D} \int \sqrt{ɛ ( ω , x , y , z )} exp ( - 2 \vert Im [ {k}_{spp , z} ] \vert z )}{\int {\int }_{D} \int exp ( - 2 \vert Im [ {k}_{spp , z} ] \vert z )} )}^{2} \qquad Formula ( 1 )$$

In the above formula (1), an integration range D is a range of a three-dimensional coordinates of the incident side portion or the output side portion relative to the plasmon excitation layer 105. In other words, the range of the x and y axes directions in the integration range D is a range that does not include a medium up to an outer peripheral surface of the entire structure of the incident side portion or an outer peripheral surface of the entire structure of the output side portion, which is a range up to an outer edge of an in-plane parallel to a surface of the plasmon excitation layer 105 facing the wavenumber vector conversion layer 107. A range of the z-axis direction in the integration range D is a range of the incident side portion or the output side portion. Assuming that an interface between the plasmon excitation layer 105 and a layer having dielectric characteristics (the dielectric layer 104 or the dielectric layer 106) adjacent to the plasmon excitation layer 105 is in a position where z=0, the range in the z-axis direction in the integration range D is a range from the interface therebetween to an infinity of a side of the plasmon excitation layer 105 facing the dielectric layer 104 or the dielectric layer 106. A direction away from the interface therebetween is assumed to be a (+) z direction in the above formula (1).

For example, when concaves and convexes are formed on the surface of the plasmon excitation layer 105, an effective dielectric constant is obtained from the formula (1) by moving an origin of the z coordinate along the concaves and convexes of the plasmon excitation layer 105. For example, when a material having an optical anisotropy is included in a calculation range for the effective dielectric constant, ∈(ω, x, y, z) becomes a vector and has a different value in each radial direction perpendicular to the z axis. That is, in each radial direction perpendicular to the z axis, there are effective dielectric constants of the incident side portion and the output side portion. In this case, the value of ∈(ω, x, y, z) is assumed to be a dielectric constant in the radial direction perpendicular to the axis z. Thus, all phenomena associated with the effective dielectric constants, such as k_{spp,z}, kₛₚₚ, and d_{eff}, have a different value in each radial direction perpendicular to the z axis.

In addition, assuming that a real part of a dielectric constant of the plasmon excitation layer 105 is ∈ₘₑₜₐₗ and a wavenumber of light in vacuum is k₀, the z component k_{spp,z} of the wavenumber of the surface plasmon and the x and y components kₛₚₚ of the wavenumber of the surface plasmon are represented by the following formulae (2) and (3):

$$\begin{matrix}{k}_{spp , z} = \sqrt{{ɛ}_{eff , spp} {k}_{0}^{2} - {k}_{spp}^{2}} & Formula ( 2 ) \\ {k}_{spp} = {k}_{0} \sqrt{\frac{{ɛ}_{eff , spp} {ɛ}_{metal}}{{ɛ}_{eff , spp} + {ɛ}_{metal}}} & Formula ( 3 )\end{matrix}$$

The effective dielectric constant ∈_{eff,spp} with respect to the surface plasmon may be calculated using a formula represented by the following formula (4), (5), or (6). However, when the integration range includes a material having a refractive index real part of less than 1, the calculation diverges. It is thus preferable to use the formula (1) or (4), and the formula (1) is particularly preferably used. When the integration range does not include any material having a refractive index real part of less than 1, the formula (5) is preferably used.

$$\begin{matrix} {ɛ}_{eff , spp} = \frac{\int {\int }_{D} \int ɛ ( ω , x , y , z ) exp ( - 2 \vert Im [ {k}_{spp , z} ] \vert z )}{\int {\int }_{D} \int exp ( - 2 \vert Im [ {k}_{spp , z} ] \vert z )} & Formula ( 4 ) \\ {ɛ}_{eff , spp} = {( \frac{\int {\int }_{D} \int Re [ \sqrt{ɛ ( ω , x , y , z )} ] exp ( 2 j {k}_{spp , z} z )}{\int {\int }_{D} \int exp ( 2 j {k}_{spp , z} z )} )}^{2} & Formula ( 5 ) \\ {ɛ}_{eff , spp} = \frac{\int {\int }_{D} \int Re [ ɛ ( ω , x , y , z ) ] exp ( 2 j {k}_{spp , z} z )}{\int {\int }_{D} \int exp ( 2 j {k}_{spp , z} z )} & Formula ( 6 )\end{matrix}$$

Herein, j represents an imaginary unit, and Im[ ] is a symbol representing the imaginary part of a numerical value in [ ]. In the formulae (4), (5), and (6), symbols in the integration ranges and the formulae are the same as those in the formula (1). However, in the formulae (5) and (6), only the x and y components kₛₚₚ of the wavenumber of the surface plasmon are as represented by the following formula (7):

$${k}_{spp} = {k}_{0} Re [ \sqrt{\frac{{ɛ}_{eff , spp} {ɛ}_{metal}}{{ɛ}_{eff , spp} + {ɛ}_{metal}}} ] \qquad Formula ( 7 )$$

In the optical element 10, a distance from the surface of the plasmon excitation layer 105 facing the light emission layer 103 to the surface of the light emission layer 103 facing the plasmon excitation layer 105 is set to be shorter than the effective interaction distance d_{eff} of the surface plasmon. Assuming that Im[ ] is a symbol representing the imaginary part of a numerical value in [ ] and the effective interaction distance of the surface plasmon is a distance in which the intensity of the surface plasmon is e⁻², the distance d_{eff} is represented by the following formula (4):

$${d}_{eff} = \vert Im [ \frac{1}{{k}_{spp , z}} ] \vert \qquad Formula ( 8 )$$

Accordingly, using the formulae (1), (2), and (3), calculation is performed by substituting, for ∈(ω, x, y, z), each of a dielectric constant distribution ∈ᵢₙ(ω, x, y, z) of the incident side portion relative to the plasmon excitation layer 105 and a dielectric constant distribution ∈ₒᵤₜ(ω, x, y, z) of the output side portion relative thereto. In this way, there are obtained an effective dielectric constant ∈_{eff,spp,in} of the incident side portion relative to the plasmon excitation layer 105 with respect to the surface plasmon and an effective dielectric constant ∈_{eff,spp,out} of the output side portion relative thereto with respect to the surface plasmon, respectively.

For example, when an in-plane perpendicular to the z axis has a dielectric anisotropy, there are effective dielectric constants of the incident side portion and the output side portion with respect to the surface plasmon in each radial direction perpendicular to the z axis. Accordingly, as described above, all phenomena associated with the effective dielectric constants, such as k_{spp,z}, kₛₚₚ, and d_{eff}, which will be described later, have a different value in each radial direction perpendicular to the z axis.

Practically, an effective dielectric constant ∈_{eff,spp} with respect to the surface plasmon can be easily obtained through repetitive calculations with the formulae (1), (2), and (3) by using an appropriate initial value as the effective dielectric constant ∈_{eff,spp} with respect to the surface plasmon.

In addition, for example, when the real part of a dielectric constant of the layer in contact with the plasmon excitation layer 105 is extremely large, the z component k_{spp,z} of the wavenumber of the surface plasmon represented by the formula (2) becomes a real number. This corresponds to non-occurrence of any surface plasmon on the interface between the layers. Thus, the dielectric constant of the layer in contact with the plasmon excitation layer 105 corresponds to an effective dielectric constant with respect to the surface plasmon in this case. Effective dielectric constants with respect to the surface plasmon in exemplary embodiments described later are also defined as in the formula (1). The above description will also be applied similarly to the formulae (4), (5), (6), and (7).

A perspective view of FIG. 2 depicts an example of arrangement of light emitting elements 201 relative to the optical element of the present exemplary embodiment. In the optical element 10, light emitted from light emitting elements 201a and 201b (the light may be hereinafter referred to as “excitation light”) is input to the light emission layer 103 from the dielectric layer 102 side. Due to such a structure, an exciton is excited in the light emission layer 103 and power of the exciton is selectively relieved to a mode attributed to the surface plasmon (surface plasmon mode) and an optical fundamental mode attributed to a waveguide structure (a waveguide fundamental mode), whereby most of the power of the exciton is emitted outside, as highly directional radiation.

Assuming that a refractive index of the dielectric layer 106 is nₒᵤₜ, a radiation angle θ_{out,spp} at which the surface plasmon mode radiates from the plasmon excitation layer 105/dielectric layer 106 interface to the dielectric layer 106 is calculated by the following formula (9):

$${θ}_{out , spp} = {sin}^{- 1} ( \frac{{k}_{spp}}{{n}_{out} {k}_{0}} ) \qquad Formula ( 9 )$$

On the other hand, assuming that a component of the wavenumber of light parallel to the plasmon excitation layer 105/dielectric layer 106 interface is k_{light}, a radiation angle θ_{out,light} at which the waveguide fundamental mode radiates from the plasmon excitation layer 105/dielectric layer 106 interface to the dielectric layer 106 is calculated by the following formula (10):

$${θ}_{out , light} = {sin}^{- 1} ( \frac{{k}_{light}}{{n}_{out} {k}_{0}} ) \qquad Formula ( 10 )$$

Herein, assuming that the real part of the effective dielectric constant of the incident side portion with respect to the optical waveguide fundamental mode is ∈_{eff,light}, the component k_{light} of the wavenumber of light parallel to the plasmon excitation layer 105/dielectric layer 106 interface is calculated by the following formula (11):

k_{light}=k₀\sqrt{∈_{eff,light}} Formula (11)

The real part ∈_{eff,light} of the effective dielectric constant of the incident side portion with respect to the optical waveguide fundamental mode is the square of an equivalent refractive index, and the equivalent refractive index is easily obtained from waveguide analysis.

A condition in which the θ_{out,spp} matches the θ_{out,light} is as represented by the following formula (12):

$${ɛ}_{eff , light} = \sqrt{\frac{{ɛ}_{eff , spp} {ɛ}_{metal}}{{ɛ}_{eff , spp} + {ɛ}_{metal}}} \qquad Formula ( 12 )$$

However, due to a phenomenon called mode dispersion, it has been thought that, in general, there is no condition in which the formula (12) holds.

The inventors of the present invention focused on a difference of light intensity distribution between surface plasmon mode and waveguide fundamental mode and repeated extensive and intensive studies. As a result, the present inventors found that there is a condition in which the formula (12) holds by increasing a dielectric constant of the vicinity of the plasmon excitation layer 105 in the incident side portion with respect to light emission wavelength and reducing a dielectric constant of a layer away from the plasmon excitation layer 105 in the incident side portion with respect to light emission wavelength. This was first found by the present inventors.

FIG. 3 depicts light intensity distributions of the surface plasmon mode and the waveguide fundamental mode. Herein, the origin of coordinates is placed on the plasmon excitation layer 105/dielectric layer 104 interface; x′ and y′ axes are assumed to be in directions along the interface; and a z′ axis is assumed to be in a direction perpendicular to the interface. A light intensity distribution 111 of the surface plasmon mode has a distribution attenuating in a direction away from the interface to the dielectric layer 104 side. On the other hand, a light intensity distribution 112 of the waveguide fundamental mode has a high light intensity distribution on the light emission layer 103 and the dielectric layer 102. Effective dielectric constant is determined according to light intensity distribution. Thus, as described above, the condition in which the formula (12) holds can be achieved by increasing the dielectric constant of the vicinity of the plasmon excitation layer 105 in the incident side portion with respect to light emission wavelength and reducing the dielectric constant of the layer away from the plasmon excitation layer 105 in the incident side portion with respect to light emission wavelength. Specifically, the refractive index of the dielectric layer 104 is reduced as compared to that of the dielectric layer 102, and the thickness of each of the layers is determined on the basis of formula (13). Herein, practically, it is unnecessary to completely satisfy the formula (13), as long as a permissible value AG of a directivity reduction width is in an allowable range.

θ_{out,spp}−θ_{out,light}=Δθ Formula (13)

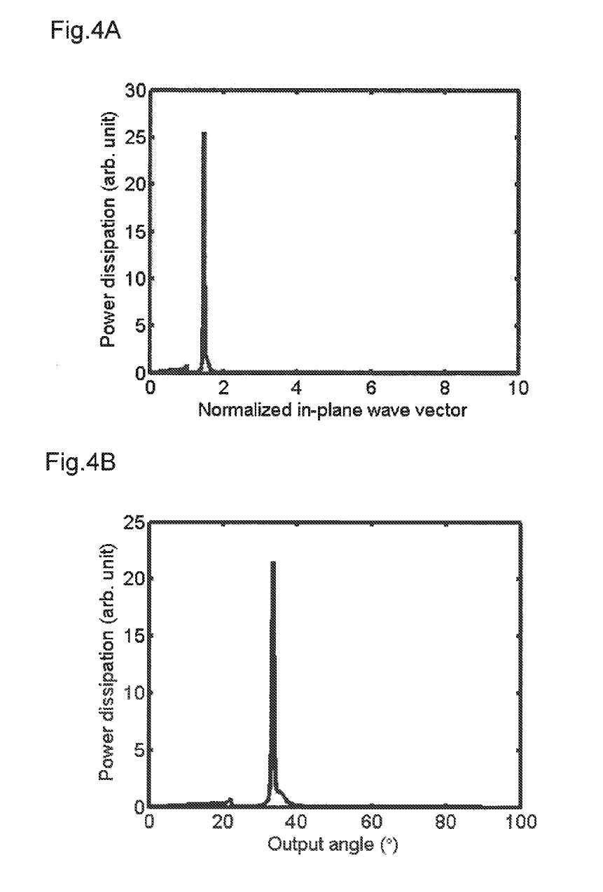

FIG. 4A depicts a normalized in-plane wavenumber dependence of dissipation power from excitons under a condition in which an output angle of the surface plasmon mode matches an output angle of the waveguide fundamental mode. FIG. 4B depicts a dependence of dissipation power from excitons on angle of output to the dielectric layer 106 under the same condition. Herein, the normalized in-plane wavenumber represents a value obtained by normalizing a wavenumber component parallel to the plasmon excitation layer 105/dielectric layer 106 interface by k₀. Since dissipation power is proportional to intensity of radiation to the dielectric layer 106, the vertical axis may be changed to represent radiation intensity. In the examples depicted in FIGS. 4A and 4B, the optical element 10 was set to the following conditions:

Dielectric layer 102: refractive index: 1.2, thickness: 40 nm

Light emission layer 103: refractive index: 1.7, thickness: 85 nm

Dielectric layer 104: refractive index: 2.3, thickness: 30 nm

Plasmon excitation layer 105: forming material: Ag, thickness: 25 nm

Dielectric layer 106: refractive index: 2.7, thickness: 0.5 mm

Wavenumber vector conversion layer 107: semispherical lens (refractive index: 2.7, diameter: 10 mm)

At a normalized in-plane wavenumber of 1.46, an extremely sharp peak and a dull peak overlap each other. This corresponds to 33 degrees as an angle of output to the dielectric layer 106. When the dissipation power component is divided into an s-polarized light component and a p-polarized light component, the s-polarized light component accounts for 58% and the p-polarized light component accounts for 42%. The s-polarized light component is derived from the waveguide fundamental mode, and the p-polarized light component is derived from the surface plasmon mode. At this time, 82% of the exciton power is used to excite the surface plasmon mode and the waveguide fundamental mode. This is a higher value than 60% as a limit value in the use of only the surface plasmon mode.

The excited modes are attenuated when they passes through the plasmon excitation layer. Considering the attenuation, 69% of the exciton power passes through to the dielectric layer 106 side under the conditions of FIG. 4.

The light emitting elements 201a and 201b emit light (excitation light) having a wavelength that can be absorbed by the light emission layer 103. Specific examples of the light emitting elements include light emitting diodes (LEDs), laser diodes, and super-luminescent diodes. Arrangement of the light emitting elements 201a and 201b relative to the optical element 10 can be any as long as the excitation light passes through the dielectric layer 102 to be emitted to the light emission layer 103.

The dielectric layer 102 is a layer including a dielectric material and is preferably made of a material that has a high refractive index with respect to light emission wavelength and does not absorb the light emission wavelength. In addition, the dielectric layer 102 is preferably made of a material that does not allow water, oxygen, and the like to pass therethrough. The dielectric layer 102 made of such a material can, for example, prevent entry of water, oxygen, and the like into the light emission layer 103, and thereby can reduce influence on a light emitter in the light emission layer 103 caused by water, oxygen, and the like. Specific examples of the material include materials with high dielectric constant, such as diamond, TiO₂, CeO₂, Ta₂O₅, ZrO₂, Sb₂O₃, HfO₂, La₂O₃, NdO₃, Y₂O₃, ZnO, and Nb₂O₅. The thickness of the dielectric layer 102 is preferably from 10 to less than 300 nm, and more preferably from 20 to less than 150 nm.

The light emission layer 103 is a layer that absorbs the excitation light to generate an exciton. The light emission layer 103 includes, for example, a light emitter. The light emission layer 103 may be made of a plurality of materials that generate, for example, light having a plurality of wavelengths in which light emission wavelengths are the same or different. The thickness of the light emission layer 103 is not particularly limited and, for example, preferably 1 μm or less, and particularly preferably 200 nm or less.

The light emission layer 103 is, for example, a layer in which the light emitter has been dispersed in a light permeable member. The light emitter is, for example, particle-shaped. Examples of the light emitter include an organic phosphor, an inorganic phosphor, and a semiconductor phosphor. From the viewpoint of absorption efficiency of the excitation light and light emission efficiency, the light emitter is preferably a semiconductor phosphor.

Examples of the organic phosphor include Rhodamine (Rhodamine 6G) and sulforhodamine (sulforhodamine 101). Examples of the inorganic phosphor include yttrium aluminium garnet, Y₂O₂S:Eu, La₂O₂S:Eu, BaMgAlₓO_{y}:Eu, BaMgAlₓO_{y}:Mn, and (Sr, Ca, Ba)₅(PO₄)₃:Cl:Eu.

Examples of the semiconductor phosphor include those having a core/shell structure, those having a multi-core/shell structure, and those in which an organic compound has been bound to the surface thereof. Specific examples of semiconductor phosphors having a multi-core/shell structure include semiconductor phosphors having a core-shell-shell structure in which, outside the shell of a semiconductor phosphor having a core-shell structure, there has been provided another shell made of another material and semiconductor phosphors having a shell-core-shell structure in which a shell is arranged at the center, a core is provided to cover the shell, and furthermore, another shell is provided to cover the outside of the core.

Examples of a material for forming the core include semiconductor materials such as group IV semiconductors, group IV-IV semiconductors, group III-V compound semiconductors, group II-VI compound semiconductors, group I-VIII compound semiconductors, and group IV-VI compound semiconductors. In addition, the material for forming the core may be a semiconductor material, for example, such as an element semiconductor in which mixed crystal consists of one element, a binary compound semiconductor in which mixed crystal consists of two elements, or a mixed crystal semiconductor in which mixed crystal consists of three or more elements. From the viewpoint of improving light emission efficiency, the core is made of, preferably, a direct transition type semiconductor material. Additionally, the semiconductor material that forms the core is preferably a material that emits visible light. In terms of durability, for example, the forming material is preferably a group III-V compound semiconductor material in which atomic bonds are strong and chemical stability is high.

From adjustment easiness for light emission spectral peak wavelength of the semiconductor phosphor, the core is preferably made of the mixed-crystal semiconductor material. On the other hand, from the viewpoint of manufacturing easiness, the core is preferably made of a semiconductor material consisting of a mixed crystal containing four elements or less.

Examples of a binary compound semiconductor material capable of forming the core include InP, InN, InAs, GaAs, CdSe, CdTe, ZnSe, ZnTe, PbS, PbSe, PbTe, and CuCl. Among them, InP and InN are preferable in terms of environmental impact and the like, and CdSe and CdTe are preferable in terms of manufacturing easiness.

Examples of a ternary mixed crystal semiconductor capable of forming the core include InGaP, AlInP, InGaN, AlInN, ZnCdSe, ZnCdTe, PbSSe, PbSTe, and PbSeTe. Among them, InGaP and InGaN are preferable from the viewpoint of manufacturing a semiconductor phosphor that is an environmentally-conscious material and hardly influenced by an external environment.

Examples of the material for the shell include semiconductor materials such as group IV semiconductors, group IV-IV semiconductors, group III-V compound semiconductors, group II-VI compound semiconductors, group I-VIII compound semiconductors, and group IV-VI compound semiconductors. In addition, the material for forming the shell may be a semiconductor material, for example, such as an element semiconductor in which mixed crystal consists of one element, a binary compound semiconductor in which mixed crystal consists of two elements, or a mixed crystal semiconductor in which mixed crystal consists of three or more elements. From the viewpoint of improving light emission efficiency, the material for forming the shell is preferably a semiconductor material having a higher band gap energy than the material for forming the core.

From the viewpoint of protection function for the core, the shell is preferably made of a group III-V compound semiconductor material in which atomic bonds are strong and chemical stability is high. On the other hand, from the viewpoint of manufacturing easiness, the shell is preferably made of a semiconductor material consisting of a mixed crystal containing four elements or less.

Examples of binary compound semiconductor materials capable of forming the shell include AlP, GaP, AlN, GaN, AlAs, ZnO, ZnS, ZnSe, ZnTe, MgO, MgS, MgSe, MgTe, CuCl, and SiC. Among them, from the viewpoint of environmental impact and the like, preferred are AlP, GaP, AlN, GaN, ZnO, ZnS, ZnSe, ZnTe, MgO, MgS, MgSe, MgTe, CuCl, and SiC.

Examples of ternary mixed crystal semiconductor materials capable of forming the shell include AlGaN, GaInN, ZnOS, ZnOSe, ZnOTe, ZnSSe, ZnSTe, and ZnSeTe. Among them, preferred are AlGaN, GaInN, ZnOS, ZnOTe, and ZnSTe from the viewpoint of manufacturing a semiconductor phosphor that is an environmentally-conscious material and hardly influenced by the external environment.

The organic compound that is to be bound to a surface of the semiconductor phosphor is, for example, preferably, an organic compound including a bonding part of an alkyl group as a function part and the core or the shell. Specific examples of the organic compound include amine compounds, phosphine compounds, phosphine oxide compounds, thiol compounds, and fatty acids.

Examples of the phosphine compounds include tributyl phosphine, trihexyl phosphine, and trioctyl phosphine.

Examples of the phosphine oxide compounds include 1-dichlorophosphinol heptane, 1-dichlorophosphinol nonane, t-butyl phosphonic acid, tetradecylphosphonic acid, dodecyldimethylphosphine oxide, dioctylphosphine oxide, didecylphosphine oxide, tributylphosphine oxide, tripentylphosphine oxide, trihexylphosphine oxide, and trioctylphosphine oxide.

Examples of the thiol compounds include tributyl sulfide, trihexyl sulfide, trioctyl sulfide, 1-heptyl thiol, 1-octyl thiol, 1-nonane thiol, 1-decane thiol, 1-undecane thiol, 1-dodecane thiol, 1-tridecane thiol, 1-tetradecane thiol, 1-pentadecane thiol, 1-hexadecane thiol, 1-octadecane thiol, dihexyl sulfide, diheptyl sulfide, dioctyl sulfide, and dinonyl sulfide.

Examples of the amine compounds include heptylamine, octylamine, nonylamine, decylamine, undecylamine, dodecylamine, tridecylamine, tetradecylamine, hexadecylamine, octadecylamine, oleylamine, dioctylamine, tributylamine, tripentylamine, trihexylamine, triheptylamine, trioctylamine, and trinonylamine.

Examples of the fatty acids include lauric acid, myristic acid, palmitic acid, stearic acid, and oleic acid.

For uses that require high monochromaticity of light emission, particle diameters of the semiconductor phosphor are preferably uniform, whereas, for uses that require high color rendering properties of light emission, particle diameters of the semiconductor phosphor are preferably nonuniform. The reason for this is that the wavelength of light emitted from the semiconductor phosphor (light emission wavelength; the same applies hereinafter) is dependent on the particle diameter of the semiconductor phosphor.

The light permeable member serves to seal the light emitter in a state in which the light emitter is dispersedly arranged in the light emission layer 103, and is preferably a member that does not absorb excitation light input to the light emission layer 103 and light emitted from the light emitter. The light permeable member is preferably made of a material that does not allow water, oxygen, and the like to pass therethrough. This structure can prevent, for example, the entry of water, oxygen, and the like into the light emission layer 103 by the light permeable member and thereby can reduce influence on the light emitter due to water, oxygen, and the like caused by water, oxygen, and the like. Accordingly, durability of the light emitter can be improved. Examples of the material for forming the light permeable member include light permeable resin materials such as silicone resin, epoxy resin, acrylic resin, fluororesin, polycarbonate resin, polyimide resin, and urea resin; and light permeable inorganic materials such as aluminium oxide, silicon oxide, and yttria.

The light emission layer 103 may include, for example, metal particles. The metal particles interacts with the excitation light to excite a surface plasmon on a surface of the metal particles and induces, near the surface thereof, an enhanced electric field nearly 100 times as much as an electric field intensity of the excitation light. The enhanced electric field can increase excitons generated in the light emission layer 103, and for example, can improve use efficiency of the excitation light in the optical element 10.

Examples of the metal for forming the metal particles include gold, silver, copper, platinum, palladium, rhodium, osmium, ruthenium, iridium, iron, tin, zinc, cobalt, nickel, chromium, titanium, tantalum, tungsten, indium, aluminium, and alloys thereof. Among them, the metal is preferably gold, silver, copper, platinum, aluminium, or an alloy containing any of them as a main component, and particularly preferably gold, silver, aluminium, or an alloy containing any thereof as a main component. The metal particles may have a structure, for example, such as a core shell structure in which a peripheral portion thereof and the center portion thereof are made of different kinds of metals; a semi-spherical alloyed structure in which two kinds of semi-spherical metals are alloyed; or a cluster-in-cluster structure in which different clusters gather together to form particles. When the metal particles are, for example, made of the alloy or have any of the above-mentioned specific structures, resonance wavelength can be controlled without changing the size, shape, and the like of the metal particles.

The shape of the metal particles can be any as long as it is a shape having a closed surface, and examples of the shape thereof include a rectangle, a cube, an ellipsoid, a sphere, a triangular pyramid, and a triangular prism. The metal particles also include, for example, those formed by processing a metal thin film into a structure composed of closed surfaces with one side length of less than 10 μm by fine processing represented by a semiconductor lithography technique. The size of the metal particles is, for example, within a range of from 1 to 100 nm, preferably within a range of from 5 to 70 nm, and more preferably within a range of from 10 to 50 nm.

The plasmon excitation layer 105 is a minute particle layer or a thin film layer formed by a forming material having a higher plasma frequency than a frequency of light occurring in the light emission layer 103 (the light may be hereinafter referred to as “light emission frequency”) when the light emission layer 103 alone is excited by excitation light. That is, the plasmon excitation layer 105 has a negative dielectric constant in the light emission frequency. On the side of the plasmon excitation layer 105 facing the light emission layer 103, there may be arranged, for example, a part of a dielectric layer having an optical anisotropy in a range from the interface of the side of the plasmon excitation layer 105 facing the light emission layer 103 to an effective interaction distance of the surface plasmon represented by the formula (8). The dielectric layer has an optical anisotropy in which dielectric constant is different depending on a direction in an in-plane perpendicular to a lamination direction of constituent elements of the optical element 10, in other words, depending on a direction in the in-plane parallel to the interface of each layer. That is, in the dielectric layer, there is a dielectric constant magnitude relationship between a certain direction and a direction orthogonal to the direction in the in-plane perpendicular to the lamination direction of the constituent elements of the optical element 10. Due to the presence of the dielectric layer, in the in-plane perpendicular to the lamination direction of the constituent elements of the optical element 10, the effective dielectric constant of the incident side portion is different between a certain direction and a direction orthogonal thereto. Then, by setting the real part of the effective dielectric constant of the incident side portion to be high to the extent where any plasmon coupling does not occur in a direction and setting the real part thereof to be low to the extent where plasmon coupling occurs in a direction orthogonal thereto, for example, an incident angle of light input to the wavenumber vector conversion layer 107 and polarized light can be further limited. Thus, for example, light extraction efficiency by the wavenumber vector conversion layer 107 can be further improved.

Theoretically, when a sum of the real part of the effective dielectric constant of the incident side portion and a real part of a dielectric constant of the plasmon excitation layer 105 is negative or zero, an exciton generated in the light emission layer 103 excites a surface plasmon on the plasmon excitation layer 105. On the other hand, when the sum is positive, the exciton does not excite any surface plasmon. That is, the above-mentioned high effective dielectric constant to the extent where any plasmon coupling does not occur is a dielectric constant where the sum of the real part of the dielectric constant of the plasmon excitation layer 105 and the real part of the effective dielectric constant of the incident side portion is positive, whereas the above-mentioned low effective dielectric constant to the extent where the plasmon coupling occurs is a dielectric constant where the sum of the real part of the dielectric constant of the plasmon excitation layer 105 and the real part of the effective dielectric constant of the incident side portion is negative or zero. The efficiency of coupling of the exciton generated in the light emission layer 103 to the surface plasmon is a condition under which the sum of the real part of the effective dielectric constant of the incident side portion and the real part of the dielectric constant of the plasmon excitation layer 105 is zero. Accordingly, in terms of increasing directivity with respect to azimuthal angle, most preferred is a condition under which a sum of the real part of the dielectric constant of the plasmon excitation layer 105 and a minimum value of the real part of the effective dielectric constant of the incident side portion is zero. However, in the case of the above condition, for example, due to excessive increase of directivity with respect to azimuthal angle, there are concerns about reduction of emitted light passing through the plasmon excitation layer 105 and heat generation in the plasmon excitation layer 105 associated therewith. Accordingly, practically, it is preferable to avoid excessive increase of directivity with respect to azimuthal angle. Specifically, in a direction of an azimuthal angle of 45 degrees, in the condition under which the sum of the real part of the dielectric constant of the plasmon excitation layer 105 and the real part of the effective dielectric constant of the incident side portion is zero, for example, high directivity radiation is obtained in ranges of azimuthal angles of from 315 to 45 degrees and from 135 to 225 degrees. Thus, for example, improvement in directivity with respect to azimuthal angle and suppression of light emission reduction can be both achieved. Examples of the material for forming the dielectric layer having the optical anisotropy include anisotropic crystals such as TiO₂, YVO₄, and Ta₂O₅ and aligned organic molecules. Examples of the dielectric layer having the optical anisotropy due to a structure thereof include an obliquely vapor-deposited film of dielectric material and an obliquely sputtered film of dielectric material. In the dielectric layer having the optical anisotropy due to the structure thereof, any forming material can also be used.

Examples of the material for forming the plasmon excitation layer 105 include gold, silver, copper, platinum, palladium, rhodium, osmium, ruthenium, iridium, iron, tin, zinc, cobalt, nickel, chromium, titanium, tantalum, tungsten, indium, aluminium, and alloys thereof. Among them, the forming material is preferably gold, silver, copper, platinum, aluminium, and a mixture with a dielectric material containing any thereof as a main component, and particularly preferably, gold, silver, aluminium, and a mixture with a dielectric material containing any thereof as a main component. The thickness of the plasmon excitation layer 105 is not particularly limited, but is preferably 100 nm or less, and particularly preferably from around 20 to 40 nm.

The surface of the plasmon excitation layer 105 facing the light emission layer 103 is preferably flat. This is because diffusion of the surface plasmon mode and the waveguide mode is suppressed.

The dielectric layer 104 is a layer including a dielectric material and is preferably made of a material that has a low refractive index with respect to light emission wavelength and does not absorb the light emission wavelength. Specific examples of the material include SiO₂ nanorod-array film and a thin film or a porous film of SiO₂, AlF₃, MgF₂, Na₃AlF₅, NaF, LiF, CaF₂, BaF₂ or a low dielectric constant plastic. The thickness of the dielectric layer 102 is in a range of preferably from 10 to less than 300 nm, and more preferably from 20 to less than 150 nm.

The dielectric layer 106 is a layer including a dielectric material and is preferably made of a material that has a high refractive index with respect to light emission wavelength and does not absorb the light emission wavelength. Specific examples of the material include materials with high dielectric constant, such as diamond, TiO₂, CeO₂, Ta₂O₅, ZrO₂, Sb₂O₃, HfO₂, La₂O₃, NdO₃, Y₂O₃, ZnO, and Nb₂O₅. The thickness of the dielectric layer 106 is not particularly limited.

The wavenumber vector conversion layer 107 is an output portion that causes light radiated from the interface between the plasmon excitation layer 105 and the dielectric layer 106 to be output from the optical element 10 by converting a wavenumber vector of the light. The wavenumber vector conversion layer 107 serves to cause the radiated light to be output from the optical element 10 in a direction substantially orthogonal to the interface between the plasmon excitation layer 105 and the dielectric layer 106.

Examples of the shape of the wavenumber vector conversion layer 107 include a surface relief lattice; a periodic structure as represented by a photonic crystal or a quasi-periodic structure; a texture structure in which a texture size thereof is larger than a wavelength of light output from the optical element 10 (for example, a surface structure made of a coarse surface); a hologram; and a microlens array. The quasi-periodic structure represents, for example, an incomplete periodic structure in which a part of the periodic structure is lacking. From the viewpoint of improvement in light extraction efficiency and directivity control, the shape of the wavenumber vector conversion layer 107 is preferably a periodic structure as represented by a photonic crystal or a quasi-periodic structure, a microlens array, or the like. The photonic crystal has preferably a crystal structure having a triangular lattice structure. The wavenumber vector conversion layer 107 may have, for example, a structure with convex portions formed on a flat plate-shaped base.

As described above, in the light emitting element 10, the distance from the surface of the plasmon excitation layer 105 facing the light emission layer 103 to the surface of the light emission layer 103 facing the plasmon excitation layer 105 is set to be shorter than the effective interaction distance d_{eff} of the surface plasmon. Setting the distance as above allows the exciton generated in the light emission layer 103 to be efficiently coupled to a free electron in the plasmon excitation layer 105, as a result of which, for example, light emission efficiency can be improved. A region with high coupling efficiency is, for example, a region from a position where the exciton is generated in the light emission layer 103 (for example, a position where the phosphor is present in the light emission layer 103) to the surface of the plasmon excitation layer 105 facing the light emission layer 103. The region is very narrow, for example, around 200 nm in thickness, and is, for example, in a range of from 1 to 200 nm or from 10 to 100 nm. In the optical element 10, when the region is in the range of from 1 to 200 nm, for example, the light emission layer 103 is preferably arranged in the range of from 1 to 200 nm from the plasmon excitation layer. In addition, when the region is in the range of from 10 to 100 nm, for example, the light emission layer 103 is preferably arranged in the range of from 10 to 100 nm from the plasmon excitation layer, and specifically, for example, the thickness of the dielectric layer 104 is set to 10 nm and the thickness of the light emission layer 103 is set to 90 nm. From the viewpoint of light extraction efficiency, the light emission layer 103 is preferably made as thin as possible. On the other hand, from the viewpoint of light output rating, the light emission layer 103 is preferably made as thick as possible. Accordingly, the thickness of the light emission layer 103 is determined, for example, on the basis of desired light extraction efficiency and light output rating. The range of the above region varies depending on the dielectric constant or the like of a dielectric layer arranged between the light emission layer and the plasmon excitation layer. Thus, for example, the thickness of the dielectric layer, the thickness of the light emission layer, and the like can be set appropriately in accordance with the range of the region under predetermined conditions.

In the optical element of the present exemplary embodiment depicted in FIG. 2, the two light emitting elements are arranged, but this is merely an example, and the number of the light emitting elements is not particularly limited. In the optical element of the present exemplary embodiment depicted in FIG. 2, the light emitting elements are arranged around the optical element 10, but the arrangement thereof is not limited to the example. The arrangement of the light emitting elements is not particularly limited as long as excitation light is input to the light emission layer 103 from the dielectric layer 102 side. Exemplary embodiments described later will not explicitly illustrate the light emitting element, but limitations on the number and arrangement of the light emitting element are the same as those in the present exemplary embodiment.

The excitation light may be, for example, input to the optical element 10 through a light guide material. Examples of the shape of the light guide material include a rectangular shape or a wedge-like shape and a shape having a light extraction structure inside a light output portion of the above shape or the light guide material. The light extraction structure is, for example, preferably one having a function of converting an incident angle of the excitation light input to the light emission layer to an angle equal to or larger than the predetermined incident angle to improve absorptivity. Surfaces of the light guide material except for the light output portion are preferably treated with a reflective material, a dielectric multi-layer film, or the like so as not to allow the excitation light to be output from the surfaces.

In addition, in the optical element of the present exemplary embodiment, the light emission layer 103 is arranged between the two dielectric layers. However, when the light emission layer 103 has also the function of the dielectric layer 102 or the dielectric layer 104, the one of the layers is not essential.

As described hereinabove, the insertion of the dielectric layers 102 and the dielectric layer 104 causes highly directional radiation with high efficiency in the optical element 10. With such a highly directional radiation with high efficiency, for example, there can be achieved an optical element that emits light with high luminance.

### Second Exemplary Embodiment

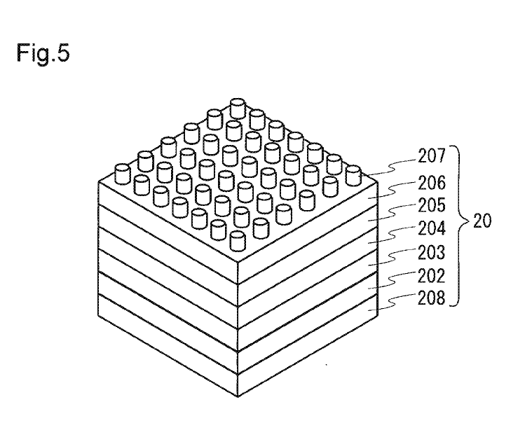

Next will be a description of another exemplary embodiment of the optical element of the present invention. A perspective view of FIG. 5 depicts a structure of a light emitting element of the present exemplary embodiment. The light emitting element of the present exemplary embodiment is different from that of the first exemplary embodiment in that it is a light emitting element configured so as to be operated by injection of current.

As depicted in FIG. 5, a light emitting element 20 of the present exemplary embodiment includes an anode 208, a hole (a positive hole) transport layer 202, a light emission layer 203 laminated on the hole transport layer 202, an electron transport layer 204 laminated on the light emission layer 203, a plasmon excitation layer 205 laminated on the electron transport layer 204, a dielectric layer 206 laminated on the plasmon excitation layer 205, and a wavenumber vector conversion layer (an output layer) 207 laminated on the dielectric layer 206. In the present exemplary embodiment, the plasmon excitation layer 205 plays a role of a cathode.

Electrons from the plasmon excitation layer 205 and holes from the anode 208 are injected into the light emitting element 20 to form excitons in the light emission layer 203. The principle of the highly directional radiation after that is the same as that in the first exemplary embodiment.

Examples of the anode layer 208 to be used include a metal thin film made of ITO, Ag, Au, Al, an alloy containing any thereof as a main component, or the like and a multi-layer film containing any of ITO, Ag, Au, and Al. Alternatively, as the anode layer 208, an anode material for forming an LED or organic EL may be similarly used. A medium around the light emitting element 20 may be any of a solid, a liquid, or a gas. A medium on a side of the light emitting element 20 facing a substrate may be different from a medium on a side thereof facing the wavenumber vector conversion layer 207.

The hole transport layer 202 may be made using a p-type semiconductor forming an ordinary LED or a semiconductor laser, an aromatic amine compound or tetraphenyldiamine used as a material of a hole transport layer for an organic EL, or the like.

The light emission layer 203 may be made using a material forming an active layer of an ordinary LED, a semiconductor laser, or an organic EL. In addition, the light emission layer 203 may be a multi-layer film having a quantum well structure.

The electron transport layer 204 may be made using an n-type semiconductor forming an ordinary LED or a semiconductor laser, Alq₃, oxadiazole (PBD), or triazole (TAZ) as a material of an electron transport layer for organic EL.

The plasmon excitation layer 205 is the same as the plasmon excitation layer 105.

The dielectric layer 206 is the same as the dielectric layer 106. However, the dielectric layer 206 is preferably formed using a transparent conductive material. This leads to in-plane evenness of current injection efficiency to suppress in-plane unevenness of luminance.

The wavenumber vector conversion layer 207 is the same as the wavenumber vector conversion layer 107.

Relative positions of the electron transport layer 204 and the hole transport layer 202 may be arranged opposite to each other in the present exemplary embodiment. In addition, a part of the surface of the plasmon excitation layer 205 may be exposed and, on the part thereof or an entire part thereof, there may be provided a cathode formed using a material different from the material of the plasmon excitation layer 205. The cathode and the anode may be a cathode and an anode forming an LED or organic EL.

In addition, FIG. 5 depicts a basic structure of the light emitting element 20 according to the present invention. Between the respective layers forming the light emitting element 20, for example, a buffer layer, and furthermore, other layers such as another hole transport layer and another electron transport layer may be inserted, and a structure of a known LED or organic EL may be applied.

In addition, in the light emitting element 20, when the anode 208 is formed using a light permeable material for a light emission wavelength of the light emission layer 203, a reflecting layer (not shown) that reflects light from the light emission layer 203 may be provided on a lower surface of the anode 208. In this structure, examples of the reflecting layer include a metal film made of Ag, Al, or the like and a dielectric multi-layer film.

### Third Exemplary Embodiment

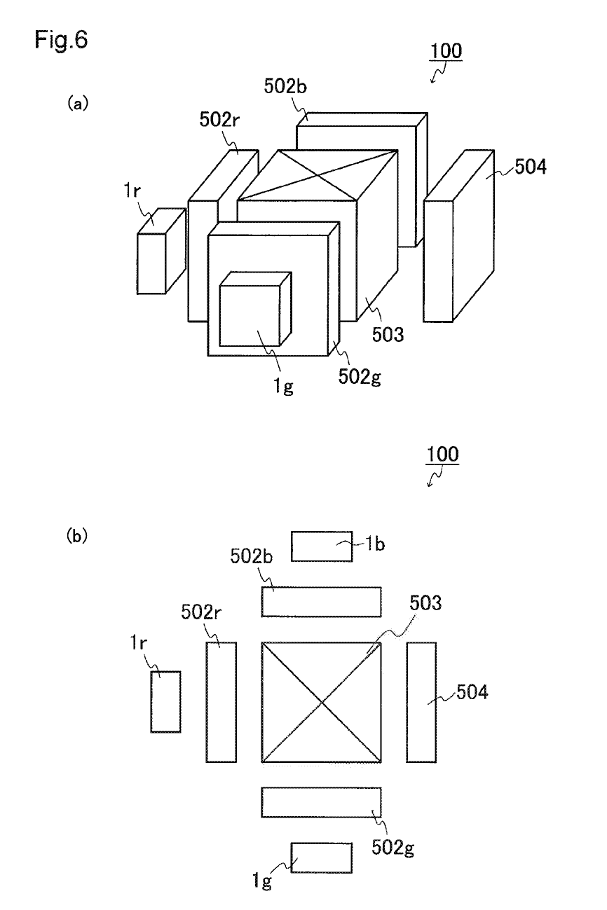

An image display device of the present exemplary embodiment is an example of a three-panel projection display device (an LED projector). FIG. 6 depict a structure of the projector of the present exemplary embodiment. FIG. 6(a) is a schematic perspective view of the LED projector of the present exemplary embodiment, and FIG. 6(b) is a top view of the projector.

As depicted in FIG. 6, a projector 100 of the present exemplary embodiment includes, as main constituent elements, three light source devices 1r, 1g, and 1b using at least one of the optical element of the first exemplary embodiment or the light emitting element of the second exemplary embodiment, three liquid crystal panels 502r, 502g, and 502b, a color synthesis optical element 503, and a projection optical system 504. The light source device 1r and the liquid crystal panel 502r, the light source device 1g and the liquid crystal panel 502g, and light source device 1b and the liquid crystal panel 502b, respectively, form optical paths.

The light source devices 1r, 1g, and 1b, respectively, are formed using different materials for red (R) light, green (G) light, and blue (B) light, respectively. The liquid crystal panels 502r, 502g, and 502b receive light output from the optical element and modulate light intensity in accordance with an image to be displayed. The color synthesis optical element 503 synthesizes light modulated by the liquid crystal panels 502r, 502g, and 502b. The projection optical system 504 includes a projection lens for projecting the light output from the color synthesis optical element 503 on a projection surface of a screen or the like.

The projector 100 modulates an image on the liquid crystal panel in each of the optical paths by a control circuit unit (not shown). The projector 100 can improve the luminance of a projected image by including the optical element of the first exemplary embodiment or the light emitting element of the second exemplary embodiment. Additionally, since the optical element exhibits very high directivity, for example, any illumination optical system does not have to be used, thus allowing miniaturization of the projector.

The projector 100 of the present exemplary embodiment depicted in FIG. 6 is the three-panel liquid crystal projector. However, the present invention is not limited to this example, and for example, the projector may be a single-panel liquid crystal projector or the like. In addition, the image display device of the present invention may be used, besides the projector 100 described above, as an image display device combined with a backlight for a liquid crystal display device or a backlight using MEMS (MicroElectro Mechanical Systems). Alternatively, the image display device of the invention may be an illumination device projecting light.

As previously described, the light emitting element of the present invention achieves highly directional radiation with high efficiency. Accordingly, the image display device using the light emitting element of the present invention can be used as a projector or the like. Examples of the projector include mobile projectors and embedded projectors embedded in next generation rear projection TV sets, digital cinemas, retinal scanning displays (RSDs), head-up displays (HUDs), mobile phones, digital cameras, notebook computers, and the like, and the projector can be used in applications across a wide range of market sectors. However, the use of the projector is not limited and applicable to various fields. Additionally, the projector can be applied to an illumination device projecting light. For example, the projector may be applied to illumination equipment, backlight, and direct-viewing display devices such as a personal digital assistant (PDA).

While the present invention has been illustrated with reference to the exemplary embodiments hereinabove, the invention is not limited thereto. Structures and details of the present invention can be changed in various forms that can be understood by those skilled in the art within the scope of the invention.

A part or an entire part of the above-described embodiments can be described as in the following supplementary notes but is not limited thereto.

(Supplementary Note 1)

An optical element including: a light emission layer, a plasmon excitation layer, an output layer, and a dielectric layer, in which the light emission layer generates an exciton to emit light; the plasmon excitation layer is arranged on an upper side than the light emission layer and has a higher plasma frequency than a light emission frequency of the light emission layer; the output layer is arranged on an upper side than the plasmon excitation layer and converts light or a surface plasmon generated on an upper surface of the plasmon excitation layer into light with a predetermined output angle to output the light; the dielectric layer is arranged at least one of on a lower side than the light emission layer and between the light emission layer and the plasmon excitation layer; a real part of an effective dielectric constant with respect to the surface plasmon is higher in an upper side portion than the plasmon excitation layer than in a lower side portion than the plasmon excitation layer; a dielectric constant with respect to the light emission frequency of the light emission layer is higher in a lowest layer than in a layer adjacent to a lower side of the plasmon excitation layer; and assuming that, in a highly directional radiation from the plasmon excitation layer to the output layer side, a radiation angle of a surface plasmon-derived highly directional radiation is θ_{out,spp} and a radiation angle of an optical waveguide fundamental mode-derived highly directional radiation is θ_{out,light}, an absolute value of a difference between the θ_{out,spp} and the θ_{out,light} is less than 10 degrees.

(Supplementary Note 2)

The optical element according to the supplementary note 1, further including a positive hole transport layer, an electron transport layer, and an electrode, in which current is injectable from outside through the electrode; the positive hole transport layer is arranged on either of an upper side or a lower side of the light emission layer; the electron transport layer is arranged on either of an upper side or a lower side of the light emission layer and on a side opposite to the positive hole transport layer; and the light emission layer generates the exciton by coupling of a positive hole injected from the positive hole transport layer and an electron injected from the electron transport layer to emit light.

(Supplementary Note 3)

The optical element according to the supplementary note 1 or 2, in which an effective dielectric constant (∈_{eff,spp}) with respect to the surface plasmon is represented by the following formula (1); a z component k_{spp,z} of a wavenumber of the surface plasmon is represented by the following formula (2); and x and y components kₛₚₚ of the wavenumber of the surface plasmon are represented by the following formula (3):

$$\begin{matrix}{ɛ}_{eff , spp} = {( \frac{\int {\int }_{D} \int \sqrt{ɛ ( ω , x , y , z )} exp ( - 2 \vert Im [ {k}_{spp , z} ] \vert z )}{\int {\int }_{D} \int exp ( - 2 \vert Im [ {k}_{spp , z} ] \vert z )} )}^{2} ; & Formula ( 1 ) \\ {k}_{spp , z} = \sqrt{{ɛ}_{eff , spp} {k}_{0}^{2} - {k}_{spp}^{2}} ; and & Formula ( 2 ) \\ {k}_{spp} = {k}_{0} \sqrt{\frac{{ɛ}_{eff , spp} {ɛ}_{metal}}{{ɛ}_{eff , spp} + {ɛ}_{metal}}} & Formula ( 3 )\end{matrix}$$

In the formulae (1) to (3), ∈_{eff,spp} represents the effective dielectric constant with respect to the surface plasmon; ∈(ω, x, y, z) represents a dielectric constant distribution of a dielectric material on the lower side than the plasmon excitation layer or on the upper side than the plasmon excitation layer; x and y represent axial directions parallel to an interface of the plasmon excitation layer; z represents an axial direction perpendicular to the interface of the plasmon excitation layer; co represents an angular frequency of light output from the light emission layer; an integration range D represents a range of three-dimensional coordinates of the lower side or the upper side than the plasmon excitation layer; k_{spp,z} represents the z component of the wavenumber of the surface plasmon; Im[ ] represents a symbol indicating an imaginary part of a numerical value in [ ]; kₛₚₚ represents the x and y components of the wavenumber of the surface plasmon; k₀ represents a wavenumber of light in vacuum; and ∈ₘₑₜₐₗ represents a real part of a dielectric constant of the plasmon excitation layer.

(Supplementary Note 4)

An illumination device including the optical element according to any of the supplementary notes 1 to 3 and a light projection unit, the illumination device being capable of projecting light by inputting light from the optical element to the light projection unit and outputting light from the light projection unit.

(Supplementary Note 5)

The illumination device according to the supplementary note 4, further including a projection optical system projecting a projected image by the light output from the light projection unit.

(Supplementary Note 6)

The illumination device according to the supplementary note 4 or 5, in which the optical element is arranged relative to the light projection unit in a direction different from a direction of light output from the light projection unit.

(Supplementary Note 7)

An image display device including the optical element according to any of the supplementary notes 1 to 3 and an image display unit, the image display device being capable of displaying an image by inputting light from the optical element to the image display unit and outputting light from the image display unit.

(Supplementary Note 8)

The image display device according to the supplementary note 7, further including a projection optical system projecting a projected image by the light output from the image display unit.

(Supplementary Note 9) The image display device according to the supplementary note 7 or 8, in which the optical element is arranged relative to the light projection unit in a direction different from a direction of light output from the light projection unit.

(Supplementary Note 10)

An operation method for the optical element according to any of the supplementary notes 1 to 3, the method including: causing the light emission layer of the optical element according to any of the supplementary notes 1 to 3 to generate an exciton, coupling power of the generated exciton to a surface plasmon-derived mode and an optical waveguide mode in the optical element, and then, emitting, as light, the power of the exciton coupled to each mode.

(Supplementary Note 11)

The operation method according to the supplementary note 10, in which the optical element is the optical element according to the supplementary note 2; current is injected into the optical element from outside through the electrode; a positive hole is injected into the light emission layer from the positive hole transport layer, an electron is injected into the light emission layer from the electron transport layer; and the positive hole and the electron are coupled together in the light emission layer to generate the exciton so as to emit light.

(Supplementary Note 12)

An operation method for the illumination device according to the supplementary notes 4 to 6, the operation method including emitting light from the optical element according to the supplementary notes 1 to 3 by the operation method according to the supplementary notes 10 to 11, inputting the light to the light projection unit from the optical element, and outputting light from the light projection unit to project the light.

(Supplementary Note 13)

The operation method according to the supplementary note 12, in which the illumination device is the illumination device according to the supplementary note 5; and the operation method further includes causing the projection optical system to project a projected image by the light output from the light projection unit.

(Supplementary Note 14)

The operation method for the image display device according to any of the supplementary notes 7 to 9, in which the method emits light from the optical element according to any of the supplementary notes 1 to 3 by the operation method according to the supplementary note 10 or 11, inputs the light to the image display unit from the optical element, and outputs light from the image display unit to display an image.

(Supplementary Note 15)

The operation method according to the supplementary note 14, in which the image display device is the image display device according to the supplementary note 8; and the method further includes causing the projection optical system to project a projected image by the light output from the image display unit.

This application is based upon and claims the benefit of priority from Japanese Patent Application No. 2012-170683, filed on Jul. 31, 2012, the disclosure of which is incorporated herein in its entirety.

### REFERENCE SIGNS LIST

1, 1r, 1g, 1b Light source device
10 Optical element
20 Light emitting element
100 LED projector (image display device)
102, 104, 106, 206 Dielectric layer
103, 203 Light emission layer
105 Plasmon excitation layer
205 Plasmon excitation layer (cathode)
107, 207 Wavenumber vector conversion layer (output layer)
202 Positive hole transport layer
204 Electron transport layer
208 Anode
201a, 201b Light emitting element
502r, 502g, 502b Liquid crystal panel
503 Color synthesis optical element
504 Projection optical system

What is claimed is:

1. An optical element comprising: a light emission layer, a plasmon excitation layer, an output layer, and a dielectric layer, wherein the light emission layer generates an exciton to emit light; the plasmon excitation layer is arranged on an upper side than the light emission layer and has a higher plasma frequency than a light emission frequency of the light emission layer; the output layer is arranged on an upper side than the plasmon excitation layer and converts light or a surface plasmon generated on an upper surface of the plasmon excitation layer into light with a predetermined output angle to output the light; the dielectric layer is arranged at least one of on a lower side than the light emission layer and between the light emission layer and the plasmon excitation layer; a real part of an effective dielectric constant with respect to the surface plasmon is higher in an upper side portion than the plasmon excitation layer than in a lower side portion than the plasmon excitation layer; a dielectric constant with respect to the light emission frequency of the light emission layer is higher in a lowest layer than in a layer adjacent to a lower side of the plasmon excitation layer; and assuming that, in a highly directional radiation from the plasmon excitation layer to the output layer side, a radiation angle of a surface plasmon-derived highly directional radiation is θ_{out,spp} and a radiation angle of an optical waveguide fundamental mode-derived highly directional radiation is θ_{out,light}, an absolute value of a difference between the θ_{out,spp} and the θ_{out,light} is less than 10 degrees.

2. The optical element according to claim 1, further comprising a positive hole transport layer, an electron transport layer, and an electrode, wherein current is injectable from outside through the electrode; the positive hole transport layer is arranged on either of an upper side or a lower side of the light emission layer; the electron transport layer is arranged on either of an upper side or a lower side of the light emission layer and on a side opposite to the positive hole transport layer; and the light emission layer generates the exciton by coupling of a positive hole injected from the positive hole transport layer and an electron injected from the electron transport layer to emit light.

3. The optical element according to claim 1, wherein an effective dielectric constant (∈_{eff,spp}) with respect to the surface plasmon is represented by the following formula (1); a z component k_{spp,z} of a wavenumber of the surface plasmon is represented by the following formula (2); and x and y components kₛₚₚ of the wavenumber of the surface plasmon are represented by the following formula (3):
$$\begin{matrix}{ɛ}_{eff , spp} = {( \frac{\int {\int }_{D} \int \sqrt{ɛ ( ω , x , y , z )} exp ( - 2 \vert Im [ {k}_{spp , z} ] \vert z )}{\int {\int }_{D} \int exp ( - 2 \vert Im [ {k}_{spp , z} ] \vert z )} )}^{2} ; & Formula ( 1 ) \\ {k}_{spp , z} = \sqrt{{ɛ}_{eff , spp} {k}_{0}^{2} - {k}_{spp}^{2}} ; and & Formula ( 2 ) \\ {k}_{spp} = {k}_{0} \sqrt{\frac{{ɛ}_{eff , spp} {ɛ}_{metal}}{{ɛ}_{eff , spp} + {ɛ}_{metal}}} & Formula ( 3 )\end{matrix}$$
In the formulae (1) to (3), ∈_{eff,spp} represents the effective dielectric constant with respect to the surface plasmon; ∈(ω, x, y, z) represents a dielectric constant distribution of a dielectric material on the lower side than the plasmon excitation layer or on the upper side than the plasmon excitation layer; x and y represent axial directions parallel to an interface of the plasmon excitation layer; z represents an axial direction perpendicular to the interface of the plasmon excitation layer; w represents an angular frequency of light output from the light emission layer; an integration range D represents a range of three-dimensional coordinates of the lower side or the upper side than the plasmon excitation layer; k_{spp,z} represents the z component of the wavenumber of the surface plasmon; Im[ ] represents a symbol indicating an imaginary part of a numerical value in [ ]; kₛₚₚ represents the x and y components of the wavenumber of the surface plasmon; k₀ represents a wavenumber of light in vacuum; and ∈ₘₑₜₐₗ represents a real part of a dielectric constant of the plasmon excitation layer.

4. An illumination device comprising the optical element according to claim 1 and a light projection unit, the illumination device being capable of projecting light by inputting light from the optical element to the light projection unit and outputting light from the light projection unit.

5. The illumination device according to claim 4, further comprising a projection optical system projecting a projected image by the light output from the light projection unit.

6. The illumination device according to claim 4, wherein the optical element is arranged relative to the light projection unit in a direction different from a direction of light output from the light projection unit.

7. An image display device comprising the optical element according to claim 1 and an image display unit, the image display device being capable of displaying an image by inputting light from the optical element to the image display unit and outputting light from the image display unit.

8. The image display device according to claim 7, further comprising a projection optical system projecting a projected image by the light output from the image display unit.

9. The image display device according to claim 7, wherein the optical element is arranged relative to the light projection unit in a direction different from a direction of light output from the light projection unit.

10. An operation method for the optical element according to claim 1 the method comprising: causing the light emission layer of the optical element according to claim 1 generate an exciton, coupling power of the generated exciton to a surface plasmon-derived mode and an optical waveguide mode in the optical element, and then, emitting, as light, the power of the exciton coupled to each mode.
